(19) United States
(12) Patent Application Publication
(10) Pub. No.: US 2021/0234337 A1
(43) Pub. Date: Jul. 29, 2021

(54) LASER OSCILLATOR AND LASER PROCESSING METHOD

(71) Applicant: Panasonic Intellectual Property Management Co., Ltd., Osaka (JP)

(72) Inventors: TAKAAKI KASSAI, Osaka (JP); TAKAYUKI YOSHIDA, Shiga (JP); AKIHIKO ISHIBASHI, Osaka (JP)

(21) Appl. No.: 17/092,841

(22) Filed: Nov. 9, 2020

(30) Foreign Application Priority Data
Jan. 27, 2020 (JP) 2020-010979

(51) Int. Cl. H01S 5/042; H01S 5/40; H01S 5/022

(52) U.S. Cl. CPC H01S 5/0428; B23K 26/53; H01S 5/02292; H01S 5/4012

(57) ABSTRACT

A laser oscillator includes a first laser diode that emits first laser light, a second laser diode that emits second laser light having a wavelength different from a wavelength of the first laser light, a first current source that drives the first laser diode, a second current source that drives the second laser diode, a combiner that superimposes the first laser light with the second laser light, and an output mirror that emits laser light combined by the combiner to the outside.

### BACKGROUND

### 1. Technical Field

The present disclosure relates to a laser oscillator and a laser processing method.

### 2. Description of the Related Art

Laser processing such as welding and cutting using a laser oscillator has been attracting attention in processing in an industrial field. Fine and high-definition processing in which spatter is unlikely to occur is possible by using laser light. Generally, a laser processing machine includes an oscillator that uses a gas laser, a fiber laser, a diode laser (semiconductor laser), or the like as light sources, and uses a plurality of lasers to superimpose laser light beams, and thus forms a high-power beam, an optical system and an optical fiber that are used to guide the beam, a head that emits the beam to a processing target, and a robot arm that moves the beam from the head to a desired position in the processing target.

As an electronic component processed by using a laser oscillator, for example, there is thin film chip resistor R1 as illustrated in FIG. 1. Chip resistor R1 includes insulating substrate 11, upper surface electrode layer 12, thin film resistor layer 14, protective film layer 16, and end surface electrode layer 17. As insulating substrate 11, for example, a substrate made of alumina ceramic or the like is used. In order to fragment chip resistor R1 as a final form, it is necessary to individually divide insulating substrate 11, and this division step can be performed by using laser light.

As illustrated in FIG. 2, break grooves 22 and 23 are formed on insulating substrate 11 before being fragmented, along grid-like division lines. Next, insulating substrate 11 is divided into individual pieces by performing an operation such as “folding” or “splitting” along break grooves 22 and 23. A laser is used to form break grooves 22 and 23 (hereinafter, this method will be referred to as laser dicing). Break grooves 22 and 23 are formed in advance on insulating substrate 11 before electrode layers and the like are formed in order to prevent debris generated during laser dicing from adhering to the electrode layers and the like. In order to prevent insulating substrate 11 from cracking along the break grooves when forming continuous break grooves, in Japanese Patent Unexamined Publication No. 2005-86131, as illustrated in FIGS. 3 and 4, break grooves including plurality of relatively shallow first holes 30 and plurality of relatively deep second holes 31 are formed along break lines 32 and 33. In Japanese Patent Unexamined Publication No. 2005-86131, a galvano-mirror type laser is used to control depths of the holes by changing energy of laser light and the number of shots, and thus forms the first holes and the second holes.

In the method disclosed in Japanese Patent Unexamined Publication No. 2005-86131, it is necessary to appropriately change energy of a laser oscillator or change the number of shots while performing scanning with the laser light at a constant speed by using a galvano mirror. However, it is difficult to change the energy or the number of pulses of the laser oscillator in a short time.

Therefore, in Japanese Patent Unexamined Publication No. 2002-28795, as illustrated in FIG. 5, there is the use of a method of coaxially superimposing fundamental wave laser light having a predetermined fundamental frequency with one or more kinds of harmonic laser light beams having frequencies that are integer multiples of the fundamental frequency. With this method, a break groove can be formed without changing oscillation conditions for a laser oscillator.

### SUMMARY

According to an aspect of the present disclosure, there is provided a laser oscillator including a first laser diode that emits first laser light; a second laser diode that emits second laser light having a wavelength different from a wavelength of the first laser light; a first current source that drives the first laser diode; a second current source that drives the second laser diode; a combiner that superimposes the first laser light with the second laser light to generate combined laser light; and an output mirror that emits the combined laser light to outside.

### BRIEF DESCRIPTION OF THE DRAWINGS

FIG. 1 is a sectional view illustrating a thin film chip resistor of the related art;

FIG. 2 is a perspective view illustrating an insulating substrate before being fragmented in the related art;

FIG. 3 is a sectional view illustrating a part of the insulating substrate before being fragmented in the related art;

FIG. 4 is a plan view illustrating a part of the insulating substrate before being fragmented in the related art;

FIG. 5 is a block diagram illustrating a laser processing apparatus of the related art;

FIG. 6 is a schematic diagram illustrating a part of a laser oscillator according to an exemplary embodiment of the present disclosure;

FIG. 7 is a block diagram illustrating a part of the laser oscillator according to the exemplary embodiment of the present disclosure;

FIG. 8 is a schematic diagram illustrating a laser processing apparatus using the laser oscillator according to an exemplary embodiment of the present disclosure;

FIG. 9 is a schematic diagram illustrating a method of controlling the laser oscillator according to the exemplary embodiment of the present disclosure;

FIG. 10 is a sectional view illustrating processing based on a laser processing method according to the exemplary embodiment of the present disclosure;

FIG. 11 is a plan view illustrating processing based on laser processing method according to the exemplary embodiment of the present disclosure;

FIG. 12 is a schematic diagram illustrating a method of controlling the laser oscillator according to the exemplary embodiment of the present disclosure;

FIG. 13 is a sectional view illustrating processing based on the laser processing method according to the exemplary embodiment of the present disclosure; and

FIG. 14 is a plan view illustrating processing based on the laser processing method according to the exemplary embodiment of the present disclosure.

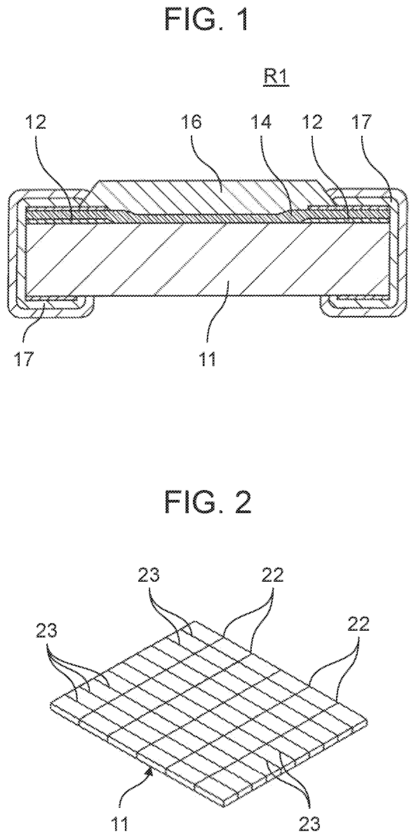

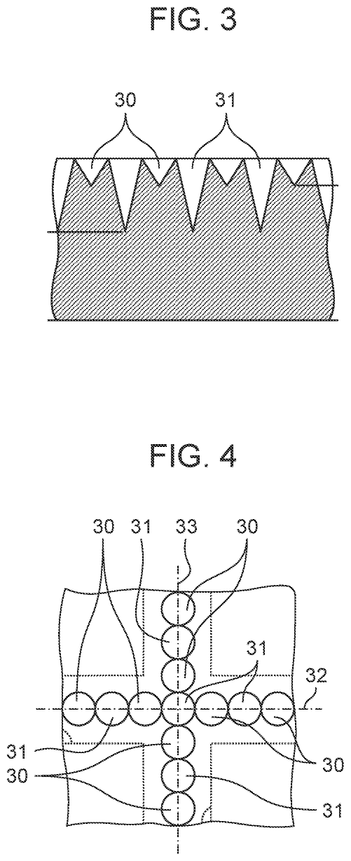

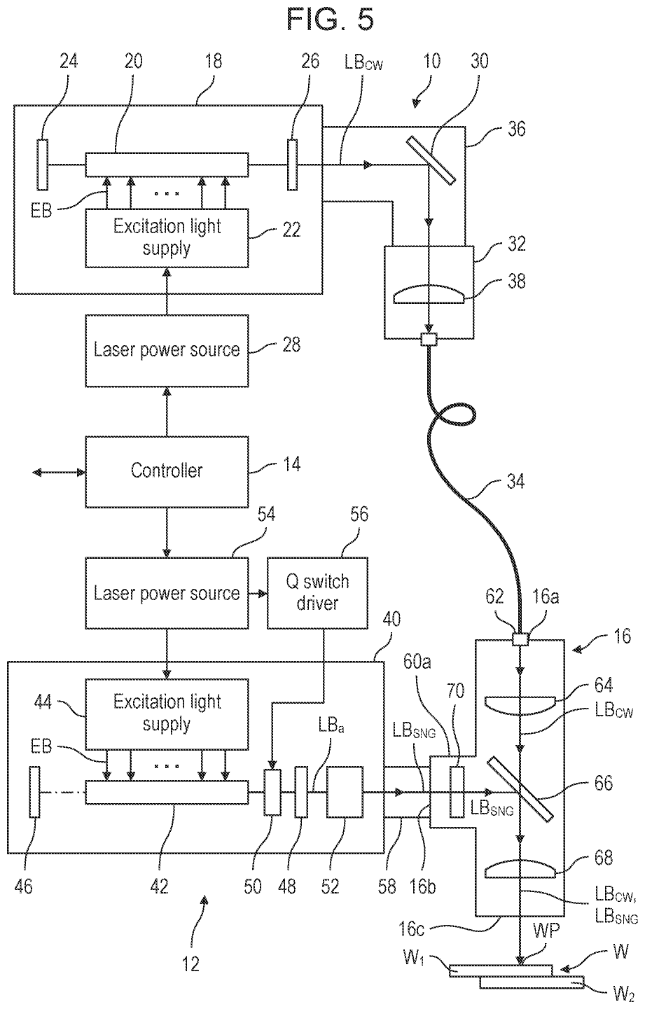

### DETAILED DESCRIPTIONS

Since an apparatus in Japanese Patent Unexamined Publication No. 2002-28795 has two or more types of laser oscillators, there is a problem that a laser processing apparatus is large-sized. Since laser light beams with different wavelengths are coaxially superimposed by using their polarization and wavelength characteristics, an optical system may be expensive and complicated to be larger-sized, so that there is concern that optical adjustment may be complicated.

An object of the present disclosure is to provide a laser oscillator that has high oscillation efficiency and can implement a small-sized laser processing apparatus, and a laser processing method.

A laser oscillator according to an aspect of the present disclosure includes a first laser diode, a second laser diode, a first current source, a second current source, a combiner, and an output mirror. The first laser diode emits first laser light. The second laser diode emits second laser light. The first current source drives the first laser diode. The second current source drives the second laser diode. The combiner superimposes the first laser light with the second laser light. The output mirror emits combined laser light to the outside. A wavelength of the first laser light and a wavelength of the second laser light are different from each other.

A laser processing method according to an aspect of the present disclosure is a laser processing method using a laser processing apparatus including the laser oscillator, the laser processing method including causing the first laser diode to perform oscillation in a pulse waveform by using the first current source; and causing the second laser diode to perform oscillation in a pulse waveform by using the second current source.

A laser processing method according to another aspect of the present disclosure is a laser processing method using a laser processing apparatus including the laser oscillator, the laser processing method including causing the first laser diode to perform oscillation in a continuous waveform by using the first current source; and causing the second laser diode to perform oscillation in a pulse waveform by using the second current source.

According to the laser oscillator and the laser processing method of the present disclosure, it is possible to increase processing efficiency.

According to the laser oscillator of the present disclosure, a first current source and a second current source are included in a single laser oscillator. Thus, the laser processing apparatus is not required to use a plurality of laser oscillators for each current. Consequently, a small-sized laser processing apparatus can be implemented. Since the first laser diode and the second laser diode that emit laser light beams having different wavelengths are controlled by different current sources, an oscillation mode, an energy amount, power, a pulse width, and the like of each laser diode can be efficiently adjusted. Thus, in the laser processing apparatus using the laser oscillator of the present disclosure, laser light can be easily optimized according to characteristics of a workpiece and a processing method.

In a case where two laser diodes that emit laser light beams having different wavelengths are controlled by only a single current source, a current loss may occur. For example, since a laser diode having an oscillation wavelength near 950 nm and a laser diode having an oscillation wavelength near 450 nm have different device structures, threshold values of current values at which laser light is oscillated are different from each other. In a case where a single power source is used, it is necessary to match specifications of a current source with those of a laser diode having the maximum current threshold value. However, by using two or more current sources, it is possible to perform control in accordance with each laser diode having an oscillation wavelength and thus to reduce a current loss.

In the laser processing apparatus, a laser diode (hereinafter, also referred to as an LD) performs pulse oscillation or continuous (CW) oscillation as necessary. However, compared with the pulse oscillation, a heating value of a current source for the continuous (CW) oscillation is great. Thus, it is necessary to sufficiently cool a current source and a laser diode that perform continuous (CW) oscillation. It is possible to separately control power sources for pulse oscillation and CW oscillation by using two or more current sources and thus to reduce a cooling load.

As described above, in the laser oscillator of the present disclosure, two laser diodes are controlled by using different current sources such that a current loss can be reduced, and thus high oscillation efficiency can be realized. Therefore, the laser processing apparatus using the laser oscillator of the present disclosure can have high processing efficiency even though the laser processing apparatus is small-sized.

Laser Oscillator

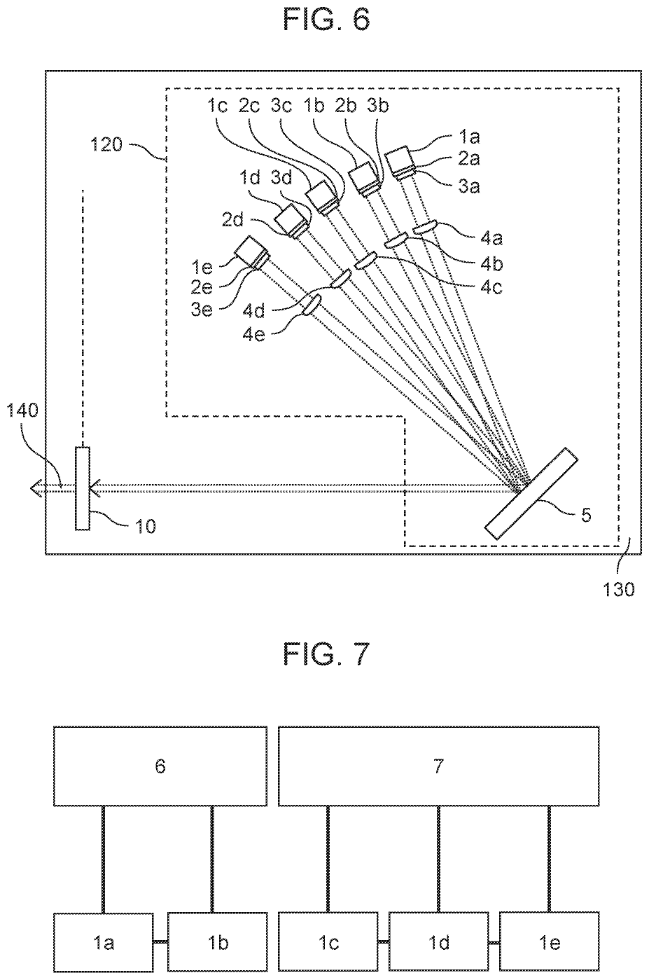

Hereinafter, a laser oscillator according to an exemplary embodiment of the present disclosure will be described in detail with reference to FIGS. 6 and 7. Laser oscillator 130 according to the present exemplary embodiment includes first laser diodes (hereinafter also referred to as first LDs) 1a and 1b, second laser diodes (hereinafter also referred to as second LDs) 1c to 1e, first current source 6, second current source 7, combiner 5, and output mirror 10.

In laser oscillator 130 according to the present exemplary embodiment, a plurality of laser light beams emitted from plurality of LDs 1a to 1e are superimposed by combiner 5 such as a diffraction grating to be condensed as a single laser beam. A propagation direction of each of the laser light beams emitted from plurality of LDs 1a to 1e is changed by combiner 5. Since each of plurality of LDs 1a to 1e is disposed separately as illustrated in FIG. 6, an incidence angle of the laser light incident to combiner 5 differs for each LD. As a result, for example, in a case where combiner 5 is a diffraction grating, when wavelengths of the laser light beams are the same as each other, a diffraction angle at which a diffraction intensity from the diffraction grating becomes maximum also differs for each LD. Similarly, for example, in a case where the combiner is a prism, when wavelengths of laser light beams are the same as each other, a transmission angle after refraction also differs for each LD.

However, the diffraction angle and the transmission angle also depend on a wavelength of the laser light. Therefore, by adjusting the wavelength of the emitted laser light for each of the LDs, the diffraction angle or the transmission angle from combiner 5 can be made constant.

Consequently, the laser light beams emitted from plurality of LDs 1a to 1e are combined into a single beam, and can thus be condensed in a specific direction without depending on a disposition of the LDs. As a result, the laser light condensed as a single beam by combiner 5 has a plurality of wavelengths (lock wavelengths) corresponding to the respective LDs.

FIG. 6 is a schematic diagram illustrating a laser light generation part of laser oscillator 130 according to the present exemplary embodiment. In the present exemplary embodiment, laser light generation based on a DDL method is used. In the present exemplary embodiment, laser light beams emitted from respective LDs 1a to 1e are condensed as a single laser light beam via first collimators 2a to 2e, rotation elements 3a to 3e, second collimators 4a to 4e, and combiner 5. The condensed laser light beam is emitted to the outside via output mirror 10. First collimators 2a to 2e, rotation elements 3a to 3e, second collimators 4a to 4e, and combiner 5 form laser light combiner 120.

Laser Diode (LD)

LDs 1a to 1e generate and emit laser light. The LD is, for example, a chip-shaped LD chip. As the LD chip, an edge emitting type (edge emitting laser: EEL) LD chip is preferably used. In the edge emitting type LD chip, for example, a long bar-shaped resonator is formed in the chip in parallel to a substrate surface. One end surface of the resonator in a longitudinal direction is covered with a film having high reflectance such that light is almost totally reflected. On the other hand, the other end surface of the resonator in the longitudinal direction is also covered with a film having high reflectance, but the reflectance is smaller than that of the reflection film provided on one end surface. Therefore, a laser beam amplified through reflection from both end surfaces and having a uniform phase is emitted from the other end surface. A length of the resonator in the longitudinal direction is referred to as a resonator length (cavity length: CL).

In a case where a plurality of resonators are provided in the LD chip, a laser beam may be emitted from a plurality of locations on the other end surface. In this case, the LD may have a plurality of light emission points. The light emission points may be arranged in a one-dimensional manner along an end surface of the chip which is the other end surface of the resonator.

As described above, laser light emitted from LDs 1a to 1e has a certain width in a wavelength band in which high power (gain) is obtained. The wavelength band in which the high power (gain) is obtained may be changed depending on the temperature of the LD chip (in other words, depending on the duration in which LDs 1a to 1e are driven). In the present exemplary embodiment, each of LDs 1a to 1e is configured such that the above-described lock wavelength is present within a wavelength band where high power (gain) is obtained at the time at which a sufficient time has elapsed from the start of driving LDs 1a to 1e and thus the power of laser light emitted from LDs 1a to 1e is stabilized.

In the present exemplary embodiment, LDs 1a and 1b correspond to first laser diodes, and LDs 1c to 1e correspond to second laser diodes. In other words, laser oscillator 130 has two first laser diodes and three second laser diodes. However, the number of laser diodes is not limited thereto, and laser oscillator 130 may have at least two laser diodes that emit laser light beams having different wavelengths. For example, laser oscillator 130 may have a single first laser diode and a single second laser diode, may have a single first laser diode and two or more second laser diodes, may have two or more first laser diodes and a single second laser diode, and may have two or more first laser diodes and two or more second laser diodes. The number of LDs may be adjusted according to the desired laser power.

In a case where laser oscillator 130 has a plurality of first laser diodes, when an average wavelength of the plurality of first laser light beams emitted from plurality of the first laser diodes is indicated by λ₁, it is preferable that each of the wavelengths of the plurality of first laser light beams is in the range of λ₁±50 nm. In other words, in the present exemplary embodiment, when the average wavelength of the laser light beams emitted from respective LDs 1a and 1b is indicated by λ₁, a wavelength of laser light emitted from each of LDs 1a and 1b is preferably in the range of λ₁±50 nm. In this case, even though laser oscillator 130 has a plurality of first laser diodes, it is possible to efficiently control oscillation of the LD by using first current source 6.

In a case where laser oscillator 130 has a plurality of second laser diodes, when the average wavelength of a plurality of second laser light beams emitted from the plurality of second laser diodes is indicated by λ₂, it is preferable that each of the wavelengths of the plurality of second laser light beams is in the range of λ₂±50 nm. In other words, in the present exemplary embodiment, when the average wavelength of the laser light beams emitted from respective LDs 1c to 1e is indicated by λ₂, a wavelength of laser light emitted from each of LDs 1c to 1e is preferably in the range of λ₂±50 nm. In this case, even though laser oscillator 130 has a plurality of second laser diodes, it is possible to efficiently control oscillation of the LD by using second current source 7.

The wavelengths of the first laser light and the second laser light are not particularly limited, and, for example, infrared laser light having a peak wavelength of 975±25 nm or 895±25 nm, or blue laser light having a peak wavelength of 400 to 450 nm may be used.

For example, a wavelength of the first laser light may be in the range from 380 nm to 500 nm. For example, a wavelength of the second laser light may be in the range from 700 nm to 1100 nm. As described above, the wavelength of the first laser light and the wavelength of the second laser light are different from each other, and thus optimum processing can be performed according to physical property of a workpiece. In a case of a material such as copper that absorbs blue laser light at about six times the absorption ratio for red laser light, the material is melted by using a blue laser beam in an initial stage of processing, and then an absorption ratio for a red laser beam is increased, so that high-power irradiation can be performed with the red laser beam. In this case, excessive power or energy input to the material can be suppressed, and thus highly accurate processing can be realized.

Laser oscillator 130 may have a laser diode other than the first laser diode and the second laser diode. For example, laser oscillator 130 may include third laser diode that emits third laser light having a wavelength different from that of the first laser light and the second laser light. Also in this case, it is possible to provide a laser oscillator having a small current loss and excellent oscillation efficiency by driving the third laser diode with a third current source different from the first current source and the second current source. In a case where laser oscillator 130 has the third laser diode, the number of the third laser diodes may be one and may be two or more.

Current Source

As illustrated in FIG. 7, laser oscillator 130 has first current source 6 that drives first laser diodes 1a and 1b and second current source 7 that drives second laser diodes 1c to 1e. In the present exemplary embodiment, as illustrated in FIG. 7, LDs 1a to 1e are connected in series to current sources 6 and 7, but may be connected in parallel thereto.

In the present exemplary embodiment, first laser diodes 1a and 1b are connected to first current source 6, but first laser diodes 1a and 1b may be respectively connected to different first current sources 6. In other words, laser oscillator 130 may have two first current sources 6, single first current source 6 may be connected to first laser diode 1a, and the other first current source 6 may be connected to first laser diode 1b.

In the present exemplary embodiment, second laser diodes 1c to 1e are connected to second current source 7, but second laser diodes 1c to 1e may be connected to different second current sources 7. In other words, laser oscillator 130 may include three second current sources 7, each of which is connected to one of second laser diodes 1c to 1e. Of course, laser oscillator 130 may have two second current sources 7, single second current source 7 may be connected to two of second laser diodes 1c to 1e, and the other second current source 7 may be connected to the remaining one of second laser diodes 1c to 1e.

First current source 6 causes first laser diodes 1a and 1b to perform oscillation in at least one of a pulse waveform and a continuous waveform. In other words, first current source 6 may perform control of pulse oscillation of first laser diodes 1a and 1b, may perform control of continuous oscillation, and may perform control of both pulse oscillation and continuous oscillation. The pulse oscillation indicates that first laser diodes 1a and 1b do not continuously oscillate laser light but intermittently repeat the oscillation for a short time. The continuous oscillation indicates that first laser diodes 1a and 1b continuously oscillate laser light.

Second current source 7 causes second laser diodes 1c to 1e to perform oscillation in at least one of a pulse waveform and a continuous waveform. In other words, second current source 7 may perform control of pulse oscillation of second laser diodes 1c to 1e, may perform control of continuous oscillation, and may perform control of both pulse oscillation and continuous oscillation.

First Collimator

In the present exemplary embodiment, light beams emitted from LDs 1a to 1e are respectively shaped by first collimators 2a to 2e. The laser light emitted from each of LDs 1a to 1e is diffused as the laser light propagates such that a beam width is increased. First collimators 2a to 2e collimate the laser light beams emitted from LDs 1a to 1e in a first direction. In other words, first collimators 2a to 2e reduce beam widths of the laser light beams emitted from LDs 1a to 1e in the first direction, and thus collimate the laser light beams. Consequently, a beam width in the first direction is reduced. The first direction indicates a direction in which the spread of the beam width is maximized. In other words, the first direction is a direction perpendicular to a substrate surface of the LD chip. The direction perpendicular to the substrate surface of the LD chip may generally be a direction of a fast axis of laser light emitted from the LD chip. On the other hand, a direction parallel to the substrate surface of the LD chip and along the light emission surface may generally be a direction of a slow axis of the laser light emitted from the LD chip. The types of first collimators 2a to 2e are not particularly limited, and may be, for example, convex lenses.

In the present exemplary embodiment, laser oscillator 130 has first collimators 2a to 2e, but the present exemplary embodiment is not limited to such an aspect, and laser oscillator 130 may not have first collimators 2a to 2e. First collimators 2a to 2e corresponding to only some of the LDs in laser oscillator 130 may be provided.

Rotation Element

In the present exemplary embodiment, light beams emitted from LDs 1a to 1e are respectively rotated by rotation elements 3a to 3e. In other words, rotation elements 3a to 3e rotate laser light beams shaped by first collimators 2a to 2e. Rotating light indicates rotating a sectional shape of a plane perpendicular to a propagation direction of light (beam).

In a case where LDs 1a to 1e are LD chips having a plurality of light emission points, a plurality of laser light beams corresponding to the light emission points are generated and emitted, and are diffused as the light beams propagate such that beam widths are increased. In this case, rotation elements 3a to 3e rotate sectional shapes of respective laser beams such that superimposition of laser light beams from different light emission points is reduced. Consequently, a high-power laser beam can be obtained.

Before passing through rotation elements 3a to 3e, sections of a plurality of laser light beams from different light emission points are parallel to substrate surfaces of the LD chips and are aligned in a direction along light emission surfaces (chip end surfaces) thereof. Since the collimation is performed by first collimators 2a to 2e, a shape of each laser light beam is a flat shape (for example, an elliptical shape or a square shape) having a minor axis in the first direction. For example, each of rotation elements 3a to 3e rotates an elliptical beam such that an angle formed between a major axis direction of the elliptical beam and the substrate surface is close to a right angle (that is, an angle formed between a minor axis direction and the substrate surface is close to 0°). For example, in a case where the first direction is a direction perpendicular to the substrate surface of the LD chip, the laser light beams can be rotated by 90° by rotation elements 3a to 3e. The types of rotation elements 3a to 3e are not particularly limited and may be convex lenses, for example. Rotation elements 3a to 3e may be provided by arranging cylindrical lenses each having an axis perpendicular to the emitting direction of the laser light and having an inclined angle of, for example, 45° with respect to the substrate surface, along the light emission point alignment direction.

First collimators 2a to 2e and the rotation elements 3a to 3e may be respectively attached to the corresponding LDs 1a to 1e. In other words, components into which LDs 1a to 1e, the corresponding first collimators 2a to 2e, and corresponding rotation elements 3a to 3e are integrated may be used.

In the present exemplary embodiment, laser oscillator 130 has rotation elements 3a to 3e, but the present exemplary embodiment is not limited to such an aspect, and laser oscillator 130 may not have the rotation elements. Rotation elements corresponding to only some of the LDs in laser oscillator 130 may be provided.

Second Collimator

In the present exemplary embodiment, light beams emitted from LDs 1a to 1e are respectively shaped by second collimators 4a to 4e. Second collimators 4a to 4e collimate, in the second direction, light beams that are shaped by first collimators 2a to 2e and are rotated by rotation elements 3a to 3e. In other words, second collimators 4a to 4e reduce a beam width of laser light in the second direction and thus collimate the laser light. Consequently, a beam width in the second direction can be reduced. In a case where rotation elements 3a to 3e are not provided, the second direction is a direction different from the first direction, for example, a direction perpendicular to the first direction. In a case where rotation elements 3a to 3e are provided, the second direction is a direction different from the first direction after rotation, for example, a direction perpendicular to the first direction after rotation. In a case where rotation elements 3a to 3e rotate laser light by 90°, the first direction and the second direction may be parallel to each other. The second direction may be the slow axis direction of the laser light emitted from the LD chip. The types of second collimators 4a to 4e are not particularly limited, and may be, for example, convex lenses.

Although laser oscillator 130 has second collimators 4a to 4e in the present exemplary embodiment, the present invention is not limited thereto, and laser oscillator 130 may not have the second collimators. Second collimators corresponding to only some of the LDs in laser oscillator 130 may be provided.

Combiner

Laser oscillator 130 has combiner 5 that superimposes the first laser light and the second laser light with each other. In the present exemplary embodiment, combiner 5 is a diffraction grating, and condenses laser light that is emitted from LDs 1a to 1e and passes through first collimators 2a to 2e, rotation elements 3a to 3e, and second collimators 4a to 4e, in a specific direction. The diffraction grating may be reflective or transmissive.

LDs 1a to 1e are disposed apart from each other in laser oscillator 130. Therefore, an incidence angle of laser light incident to the diffraction grating differs for each of LDs 1a to 1e. In general, a diffraction angle at which a diffraction intensity is the maximum depends on an incidence angle. Therefore, when wavelengths of laser light beams emitted from the LDs are the same as each other, a diffraction angle also differs for each LD, and thus it is difficult to condense the light beams in the same direction.

However, since a diffraction angle also depends on a wavelength, wavelengths of laser light beams emitted from LDs 1a to 1e are made different from each other, and, thus even when incidence angles to the diffraction grating are different from each other for respective LDs 1a to 1e, the laser light beams emitted from LDs 1a to 1e can be condensed in a specific direction with a constant diffraction angle. A wavelength at which laser light emitted from each of LDs 1a to 1e is diffracted in the specific direction is referred to as a lock wavelength. The lock wavelength differs for each LD 1a to 1e.

Therefore, the laser light condensed by the diffraction grating has a plurality of different wavelengths (lock wavelengths) for respective LDs 1a to 1e. In other words, a plurality of laser light beams having wavelength distributions each having a different lock wavelength as a peak are superimposed on the laser light condensed by the diffraction grating.

Combiner 5 is not limited to the diffraction grating, and a combiner using a wavelength difference, a combiner using polarization characteristics, and a spatial combiner may be used. The combiner using the wavelength difference may combine laser light beams having different wavelengths with each other by using, for example, a dichroic mirror or a prism. The combiner using the polarization characteristics of laser light may combine laser light beams with each other by using, for example, a polarization beam splitter such that an angle formed between a polarization direction of one laser light beam and a polarization direction of another laser light beam is 90 degrees. The spatial combiner may spatially combine laser light beams with each other by using, for example, a condenser lens or a mirror.

Output Mirror

Output mirror 10 reflects laser light obtained through superimposition and condensing in combiner 5 except for a part thereof and thus returns the laser light to LDs 1a to 1e side. Consequently, the laser light is externally resonated in laser oscillator 130. The part of the laser light of which power is increased through the external resonance is transmitted through output mirror 10 to be emitted to the outside.

Laser Processing Apparatus

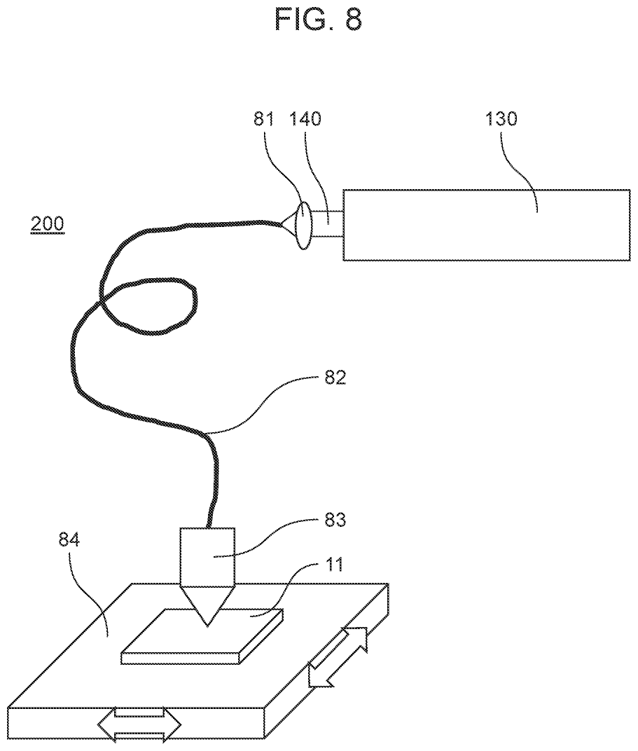

FIG. 8 is a schematic diagram illustrating laser processing apparatus 200 using laser oscillator 130 of the present disclosure. Emitted laser light 140 that is emitted from laser oscillator 130 is condensed by incidence condensing optical system 81 and is introduced into transmission optical fiber 82. The laser light that is guided to emission condensing optical system 83 to be condensed by transmission optical fiber 82 is applied to insulating substrate 11 that is a workpiece. Insulating substrate 11 is processed by being scanned by XY movement table 84 at a constant speed.

Although insulating substrate 11 is used as a workpiece in the present exemplary embodiment, the present exemplary embodiment is not limited thereto, and a workpiece that can be processed by laser processing apparatus 200 may be processed.

Laser Processing Method

A laser processing method using laser processing apparatus 200 including laser oscillator 130 of the present disclosure will be described.

First Exemplary Embodiment of Laser Processing Method

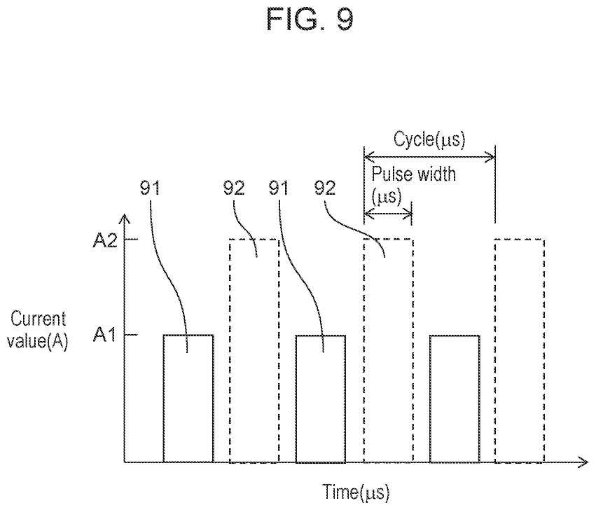

A laser processing method according to a first exemplary embodiment of the present disclosure will be described with reference to FIGS. 9 to 11. FIG. 9 illustrates a method of driving current sources 6 and 7 driving LDs 1a to 1e in the method of controlling laser oscillator 130. When a pulse drive current is applied to current sources 6 and 7, LDs 1a to 1e oscillate pulsed laser light. Pulse waveform 91 and pulse waveform 92 respectively represent pulse waveforms of currents applied to current sources 6 and 7. The power of laser light oscillated from the LD 1a to 1e can be changed according to applied current values. An elapsed time of an oscillated pulse is referred to as a pulse width (μs), and an interval between adjacent pulses is referred to as a cycle (μs).

In FIG. 9, assuming that power of laser light oscillated from LD 1a and LD 1b is W1 (W) and a pulse width is t1 (μs) when a current value applied to first current source 6 is A1 (A), energy E1 of the laser light oscillated from the LD 1a and LD 1b is E1=W1/t1 (J). Similarly, assuming that power of laser light oscillated from LD 1c to LD 1e is W2 (W) and a pulse width is t2 (μs) when a current value applied to second current source 7 is A2 (A), energy E2 of the laser light oscillated from the LD 1c to LD 1e is E2=W2/t2 (J). Since two LDs are connected to first current source 6 and three LDs are connected to second current source 7, the energy of laser light oscillated from the LDs connected to first current source 6 is E1×2 (J), and the energy of laser light oscillated from the LDs connected to second current source 7 is E2×3 (J).

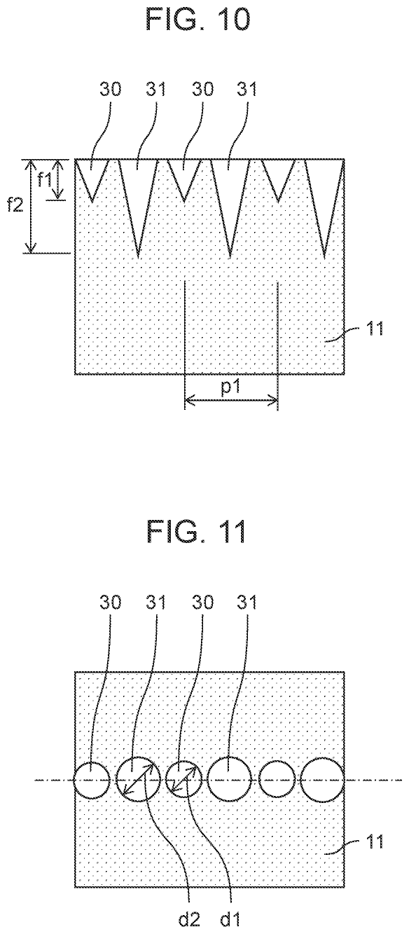

FIGS. 10 and 11 are respectively a sectional view and a plan view of insulating substrate 11 in which first hole 30 and second hole 31 are formed by irradiating insulating substrate 11 with laser light according to the control method illustrated in FIG. 9 by using laser processing apparatus 200 in FIG. 8. First hole 30 is a hole processed by laser light oscillated from LDs 1a and 1b driven by first current source 6, and second hole 31 is a hole processed by laser light oscillated from LDs 1c to 1e driven by second current source 7.

The energy of the laser light oscillated from LDs 1c to 1e driven by second current source 7 is higher than the energy of the laser light oscillated from LDs 1a and 1b driven by first current source 6. Therefore, as illustrated in FIG. 10, processing depth f2 of second hole 31 is larger than processing depth f1 of first hole 30. As illustrated in FIG. 11, processing diameter d2 of second hole 31 is larger than processing diameter d1 of first hole 30.

Pitch p1 (refer to FIG. 10) between first holes 30 may be represented by p1=V×T when a pulse cycle of first current source 6 is T (μs) and a transport speed of insulating substrate 11 is V (mm/s).

Second Exemplary Embodiment of Laser Processing Method

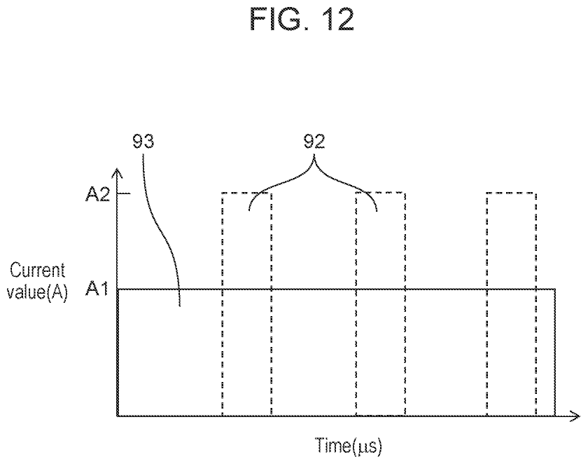

A laser processing method according to a second exemplary embodiment of the present disclosure will be described with reference to FIGS. 12 to 14. FIG. 12 illustrates a method of driving current sources 6 and 7 driving LDs 1a to 1e in the method of controlling laser oscillator 130. When a continuous drive current is applied to first current source 6, LDs 1a and 1b oscillate continuous laser light. On the other hand, a pulse drive current is applied to second current source 7, and LDs 1c to 1e oscillate pulsed laser light. Continuous waveform 93 and pulse waveform 92 respectively represent waveforms of currents applied to current sources 6 and 7. The power of laser light oscillated from the LD 1a to 1e can be changed according to an applied current value. An elapsed time of an oscillated pulse is referred to as a pulse width (μs), and an interval between adjacent pulses is referred to as a cycle (μs).

In FIG. 12, when a current value applied to first current source 6 is constant A1 (A), laser light oscillated from LD 1a and LD 1b is oscillated as continuous light (CW). The power of laser light oscillated from LDs 1a and 1b connected to first current source 6 is W1×2 (W), and the energy of laser light oscillated from LDs 1c to 1e connected to second current source 7 is E2×3 (J).

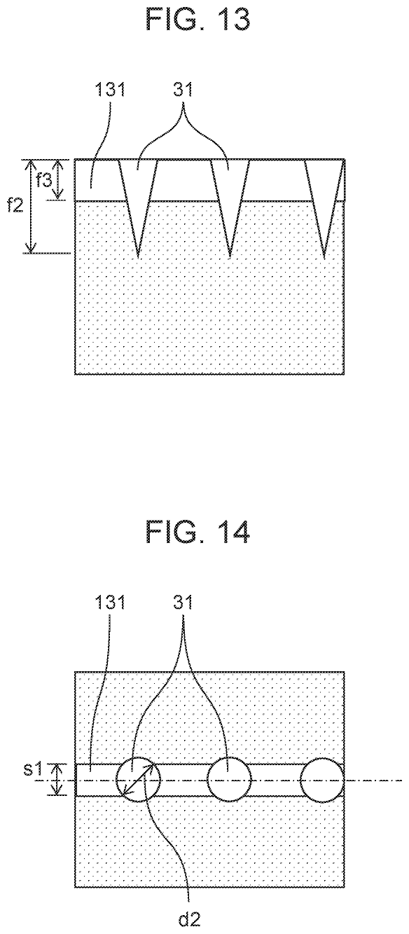

FIGS. 13 and 14 are respectively a sectional view and a plan view of insulating substrate 11 in which first processed groove 131 and second hole 31 are formed by irradiating insulating substrate 11 with laser light according to the control method in FIG. 12 by using laser processing apparatus 200 in FIG. 8. First processed groove 131 is a groove processed by laser light oscillated from LDs 1a and 1b driven by first current source 6, and second hole 31 is a hole processed by laser light oscillated from LDs 1c to 1e driven by second current source 7.

A groove depth of first processed groove 131 formed by the laser light oscillated from LDs 1a and 1b driven by first current source 6 is f3 (refer to FIG. 13), and a groove width thereof is s1 (refer to FIG. 14).

Needless to say, LDs 1a and 1b may oscillate pulsed laser light, and LDs 1c to 1e may oscillate continuous laser light. Needless to say, both LDs 1a and 1b and LDs 1c to 1e may oscillate continuous laser light.

The laser oscillator and the laser processing method of the present disclosure are useful in a method of manufacturing an electronic component, particularly in a step of dividing an insulating substrate through cutting to pick up a plurality of electronic components.

What is claimed is:

1. A laser oscillator comprising:
a first laser diode that emits first laser light;
a second laser diode that emits second laser light having a wavelength different from a wavelength of the first laser light;
a first current source that drives the first laser diode;
a second current source that drives the second laser diode;
a combiner that superimposes the first laser light with the second laser light to generate combined laser light; and
an output mirror that emits the combined laser light to outside.

2. The laser oscillator of claim 1,
wherein the first current source causes the first laser diode to perform oscillation in at least one of a pulse waveform and a continuous waveform.

3. The laser oscillator of claim 1,
wherein the second current source causes the second laser diode to perform oscillation in at least one of a pulse waveform and a continuous waveform.

4. The laser oscillator of claim 1,
wherein the laser oscillator includes a plurality of first laser diodes each being the first laser diode, and
when an average wavelength of wavelengths of a plurality of first laser light beams emitted from the plurality of first laser diodes is indicated by λ₁, a wavelength of each of the plurality of first laser light beams is in a range of λ₁±50 nm.

5. The laser oscillator of claim 4,
wherein the average wavelength λ₁ is in a range from 380 nm to 500 nm.

6. The laser oscillator of claim 1,
wherein the laser oscillator includes a plurality of second laser diodes each being the second laser diode, and
when an average wavelength of wavelengths of a plurality of second laser light beams emitted from the plurality of second laser diodes is indicated by λ₂, a wavelength of each of the plurality of second laser light beams is in a range of λ₂±50 nm.

7. The laser oscillator of claim 6,
wherein the average wavelength λ₂ is in a range from 700 nm to 1100 nm.

8. A laser processing method using a laser processing apparatus including the laser oscillator of claim 1, the laser processing method comprising:
causing the first laser diode to perform oscillation in a pulse waveform by using the first current source; and
causing the second laser diode to perform oscillation in a pulse waveform by using the second current source.

9. A laser processing method using a laser processing apparatus including the laser oscillator of claim 1, the laser processing method comprising:
causing the first laser diode to perform oscillation in a continuous waveform by using the first current source; and
causing the second laser diode to perform oscillation in a pulse waveform by using the second current source.
